(19) United States
(12) Patent Application Publication
(10) Pub. No.: US 2025/0218822 A1
(43) Pub. Date: Jul. 3, 2025

(54) APPARATUS AND METHOD OF PROCESSING SUBSTRATE

(71) Applicant: SEMES CO., LTD., Cheonan-si (KR)

(72) Inventors: Seong Hyeon KIM, Cheonan-si (KR); Dae Hun KIM, Pyeongtaek-si (KR); Hyun Woo BAE, Seoul (KR); Seung Eun NA, Bucheon-si (KR); Seung Yoon NOH, Cheonan-si (KR); Kwang Wook LEE, Seongnam-si (KR)

(73) Assignee: SEMES CO., LTD., Cheonan-si (KR)

(21) Appl. No.: 19/005,312

(22) Filed: Dec. 30, 2024

(30) Foreign Application Priority Data
Dec. 28, 2023 (KR) 10-2023-0195329

(51) Int. Cl. H01L 21/67

(52) U.S. Cl. CPC H01L 21/6715

(57) ABSTRACT

Disclosed are a substrate processing method and a substrate processing apparatus, and more particularly, a substrate processing apparatus which treats a substrate by adjusting airflow supplied to a process space. The apparatus of treating the substrate includes: a housing having an upper wall and providing an interior space; a treatment container provided in the interior space and providing a process space with an open top; a support unit for supporting a substrate within the process space; a liquid supply unit for supplying a treatment liquid on the substrate supported by the support unit; an exhaust unit for exhausting the process space; a fan for supplying descending airflow into the interior space; and an airflow distribution unit that is disposed under the fan and above the treatment container and distributes the descending airflow to the interior space, in which the airflow distribution unit is provided to distribute the descending airflow in a mode selected from a first mode and a second mode, and in the first mode and the second mode, a flow of the descending airflow is provided differently from each other.

### CROSS-REFERENCE TO RELATED APPLICATIONS

This application claims priority to and the benefit of Korean Patent Application No. 10-2023-0195329 filed in the Korean Intellectual Property Office on Dec. 28, 2023, the entire contents of which are incorporated herein by reference.

TECHNICAL FIELD

The present invention relates to a substrate processing method and a substrate processing apparatus, and more particularly, to a substrate processing apparatus which processes a substrate by adjusting airflow supplied to a process space.

### BACKGROUND ART

A semiconductor process includes a process of cleaning a thin film, foreign substances, particles, and the like on a substrate. These processes are accomplished by placing a substrate on a spin head with a patterned side facing up or down, supplying a treatment liquid to the substrate while the spin head is rotated, and subsequently drying the wafer. During these processes, the descending airflow is supplied to the chamber through a fan filter unit (FFU) to control the atmosphere of the chamber. Since several types of treatment liquids are used, and characteristics of each treatment liquid are different, the atmosphere in the chamber required for each treatment liquid is different. However, the descending airflow is supplied onto the substrate without a separate distribution means. Therefore, there is a problem that the flow of the descending airflow cannot be controlled according to the type of treatment liquid.

### SUMMARY OF THE INVENTION

The present invention has been made in an effort to provide a substrate processing apparatus and method capable of improving substrate processing efficiency when a substrate is processed by supplying a temperature and concentration-adjusted treatment liquid to a substrate.

The present invention has been made in an effort to provide a substrate processing apparatus and method capable of shortening the time required to control a concentration of a treatment liquid in a supply tank structure that adjusts the concentration of the treatment liquid by evaporation of water.

The problem to be solved by the present invention is not limited to the above-mentioned problems, and the problems not mentioned will be clearly understood by those skilled in the art from the descriptions below.

An exemplary embodiment of the present invention provides an apparatus of treating a substrate, the apparatus comprising: a housing having an upper wall and providing an interior space; a treatment container provided in the interior space and providing a process space with an open top; a support unit for supporting a substrate within the process space; a liquid supply unit for supplying a treatment liquid on the substrate supported by the support unit; an exhaust unit for exhausting the process space; a fan for supplying descending airflow into the interior space; and an airflow distribution unit that is disposed under the fan and above the treatment container and distributes the descending airflow to the interior space, wherein the airflow distribution unit is provided to distribute the descending airflow in a mode selected from a first mode and a second mode, and in the first mode and the second mode, a flow of the descending airflow may be provided differently from each other.

According to the exemplary embodiment of the present invention the airflow distribution unit includes: a fixing plate; a moving plate stacked on the fixing plate; and a driver for driving the moving plate, and the fixing plate has: a first region where a plurality of first holes penetrating in a vertical direction is formed; and a second region surrounding the first region and having a plurality of second holes penetrating in the vertical direction, the moving plate includes a plurality of third holes penetrating in the vertical direction, the moving plate is provided to be movable between a first position and a second position, and when viewed from above, the first position is a position where the moving plate overlaps the first region, and the second position may be a position where the moving plate is deviated from the first region.

According to the exemplary embodiment of the present invention an aperture ratio per unit area of the first hole in the first region may be different from an aperture ratio per unit area of the second hole in the second region.

According to the exemplary embodiment of the present invention an aperture ratio per unit area of the first hole in the first region may be greater than an aperture ratio per unit area of the second hole in the second region.

According to the exemplary embodiment of the present invention the first hole, the second hole, and the third hole have the same diameter.

According to the exemplary embodiment of the present invention the moving plate includes a first plate and a second plate, the first plate and the second plate are provided to be movable in directions facing each other or in directions opposite to each other, and the driver may be provided to move the first plate and the second plate between the first position and the second position.

According to the exemplary embodiment of the present invention the first mode allows a flow of the descending airflow to be concentrated in the process space compared to the second mode.

According to the exemplary embodiment of the present invention the second mode more uniformly provides the flow of the airflow in the interior space than the first mode.

According to the exemplary embodiment of the present invention in the first mode, when viewed from above, the moving plate may be located in the second region and the third hole overlaps the second hole.

According to the exemplary embodiment of the present invention in the second mode, the moving plate may be located in the first region when viewed from above, and the third hole overlaps the first hole.

According to the exemplary embodiment of the present invention the driver moves the moving plate to the first position when the treatment liquid is a first liquid, and moves the moving plate to the second position when the treatment liquid is a second liquid.

According to the exemplary embodiment of the present invention when the substrate is processed with the first liquid, fumes are generated more than the second liquid, and when the substrate is processed with the second liquid, low humidity may be required compared to the first liquid.

According to the exemplary embodiment of the present invention the first region has a circular shape, and when viewed from above, the first region has a size corresponding to an opening of the treatment container through which the descending airflow flows into the process space.

An exemplary embodiment of the present invention provides a method of processing a substrate by using a substrate processing apparatus that includes a housing providing an interior space and a chamber that is placed in the interior space and provides a process space of treating the substrate, the method comprising: a first process operation of processing the substrate by supplying a first liquid to the substrate located in the process space in a state where descending airflow is provided to the interior space and the process space; a second process operation of processing the substrate by supplying a second liquid to the substrate in a state where the descending airflow is provided to the interior space and the process space, wherein in the second process operation, the descending airflow more intensively flows to the process space than in the first process operation, and in the second process operation, the descending airflow flows more uniformly to the interior space and the process space than in the first process operation.

According to the exemplary embodiment of the present invention in the first process operation, the descending airflow flowing into the process space flows through the plurality of injection holes more than the descending airflow flowing into the interior space excluding the process space.

According to the exemplary embodiment of the present invention in the second process operation, the descending airflow flows into the process space through a plurality of injection holes of the same diameter.

According to the exemplary embodiment of the present invention fumes are further exhausted from the process space during the first process operation compared to the second process operation, and during the second process operation, the humidity of the process space may be maintained lower than that of the first process operation.

An exemplary embodiment of the present invention provides an apparatus of treating a substrate, the apparatus comprising: a housing having an upper wall and providing an interior space; a treatment container that is provided in the interior space, has an opening with an open top, and provides a process space; a support unit for supporting and rotating the substrate within the process space; a liquid supply unit for supplying a treatment liquid on the substrate supported by the support unit; an exhaust unit for exhausting the process space; a fan placed on an upper wall of the housing and supplying descending airflow into the interior space; and an airflow distribution unit that is disposed under the fan and above the treatment container and distributes the descending airflow to the interior space, wherein the airflow distribution unit is provided to distribute the descending airflow to the interior space in a mode selected from a first mode and a second mode, in the first mode and the second mode, the flow of the descending airflow is provided differently from each other, the airflow distribution unit includes: a fixing plate; a moving plate stacked on the fixing plate; and a driver for moving the moving plate, and the fixing plate has: a first region where a plurality of first holes penetrating in a vertical direction is formed; and a second region surrounding the first region and having a plurality of second holes penetrating in the vertical direction, and an aperture ratio per unit area of the first hole in the first region may be greater than an aperture ratio per unit area of the second hole in the second region.

According to the exemplary embodiment of the present invention when the treatment liquid is a first liquid, the airflow distribution unit operates in the first mode, in the first mode, the moving plate is located in the second region, the second hole and the third hole overlap, and when the treatment liquid is a second liquid, the airflow distribution unit operates in the second mode, and in the second mode, the moving plate may be located in the first region, and the first hole and the third hole overlap.

According to the exemplary embodiment of the present invention wherein the first liquid is a treatment liquid that generates more fumes during the substrate treatment than the second liquid, and the second liquid may be a treatment liquid required to have a lower humidity in the process space when processing the substrate than the first liquid.

According to the exemplary embodiment of the present invention, it is possible to differently provide a flow of descending airflow flowing to a process space and an interior space depending on the treatment liquid.

Further, according to the exemplary embodiment of the present invention, it is possible to uniformly provide descending airflow flowing through the process space and the interior space.

Further, according to the exemplary embodiment of the present invention, when the substrate is processed with a Sulfuric Peroxide Mixture (SPM), it is possible to more intensively provide descending airflow to the process space.

Further, according to the exemplary embodiment of the present invention, a process space may be provided at a low humidity.

Further, according to the exemplary embodiment of the present invention, it is possible to more effectively exhaust fumes generated from the treatment liquid.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

FIG. 1 is a top plan view schematically illustrating a substrate processing apparatus according to an exemplary embodiment of the present invention.

FIG. 2 is a diagram schematically illustrating an exemplary embodiment of a liquid processing chamber of FIG. 1.

FIG. 3 is a diagram illustrating an airflow distribution unit of FIG. 2.

FIG. 4 is a diagram illustrating a fixing plate of the airflow distribution unit of FIG. 3.

FIG. 5 is a diagram illustrating the airflow distribution unit in a first mode when viewed from above.

FIG. 6 is a cross-sectional view illustrating a cross-section of the airflow distribution unit of FIG. 5.

FIG. 7 is a diagram illustrating the airflow distribution unit in a second mode when viewed from above.

FIG. 8 is a cross-sectional view illustrating a cross-section of the airflow distribution unit of FIG. 7.

FIG. 9 is a cross-sectional view illustrating a cross-section of the substrate processing apparatus in which the airflow distribution unit operates in the first mode in a first processing operation.

FIG. 10 is a cross-sectional view illustrating a cross-section of the substrate processing apparatus in which the airflow distribution unit operates in the second mode in a second processing operation.

### DETAILED DESCRIPTION

Hereinafter, an exemplary embodiment of the present invention will be described in more detail with reference to the accompanying drawings. The exemplary embodiment of the present invention may be modified in various forms, and the scope of the present invention should not be construed as being limited to the following exemplary embodiments. This exemplary embodiment is provided to more completely explain the present invention to those of ordinary skill in the art. Therefore, the shapes of elements in the drawings are exaggerated to emphasize a clearer description.

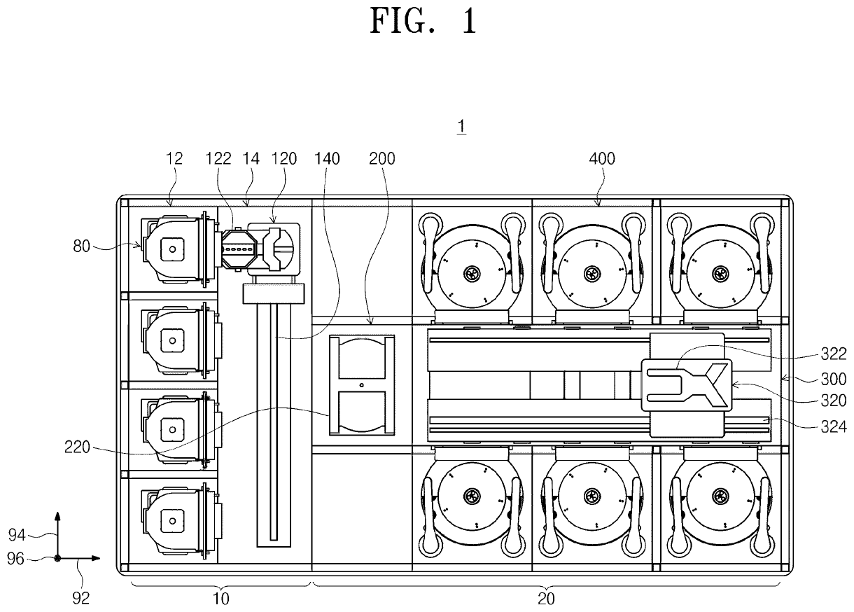

FIG. 1 is a top plan view schematically illustrating a substrate processing apparatus according to an exemplary embodiment of the present invention.

Referring to FIG. 1, a substrate processing apparatus includes an index module 10, a processing module 20, and a controller 30. According to the exemplary embodiment, the index module 10 and the processing module 20 are disposed along one direction. Hereinafter, the direction in which the index module 10 and the processing module 20 are disposed is referred to as a first direction 92, and when viewed from above, a direction vertical to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the processing module 20, and makes the substrate W, which has been completely processed in the processing module 20, be accommodated in the container 80. A longitudinal direction of the index module 10 is provided in the second direction 94. The index module 10 includes a load port 12 and an index frame 14. Based on the index frame 14, the load port 12 is located at a side opposite to the processing module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal is the second direction 94 is provided within the index frame 14, and the index robot 120 may be provided to be movable on the guide rail 140. The indexing robot 120 includes a hand 122 on which the substrate W is placed, and the hand 122 may be provided to be movable forward and backward, rotatable about the third direction 96, and movable along the third direction 96. A plurality of hands 122 are provided to be spaced apart in the vertical direction, and the hands 122 may move forwardly and backwardly independently of each other.

The processing module 20 includes a buffer unit 200, a transfer chamber 300, and a processing chamber 400. The buffer unit 200 provides a space in which the substrate W loaded into the processing module 20 and the substrate W unloaded from the processing module 20 stay temporarily. The processing chamber 400 performs a treatment process of liquid-treating the substrate W by supplying a liquid onto the substrate W. The transfer chamber 300 transfers the substrate W between the buffer unit 200 and the liquid processing chamber 400.

The transfer chamber 300 may be provided so that a longitudinal direction is the first direction 92. The buffer unit 200 may be disposed between the index module 10 and the transfer chamber 300. A plurality of liquid processing chambers 400 is provided and may be disposed on the side of the transfer chamber 300. The liquid processing chamber 400 and the transfer chamber 300 may be disposed in the second direction 94. The buffer unit 200 may be located at one end of the transfer chamber 300.

According to the example, the liquid processing chambers 400 are respectively disposed on both sides of the transfer chamber 300. At each of both sides of the transfer device 300, the liquid processing devices 400 may be provided in an array of A×B (each of A and B is 1 or a natural number larger than 1) in the first direction 92 and the third direction 96.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

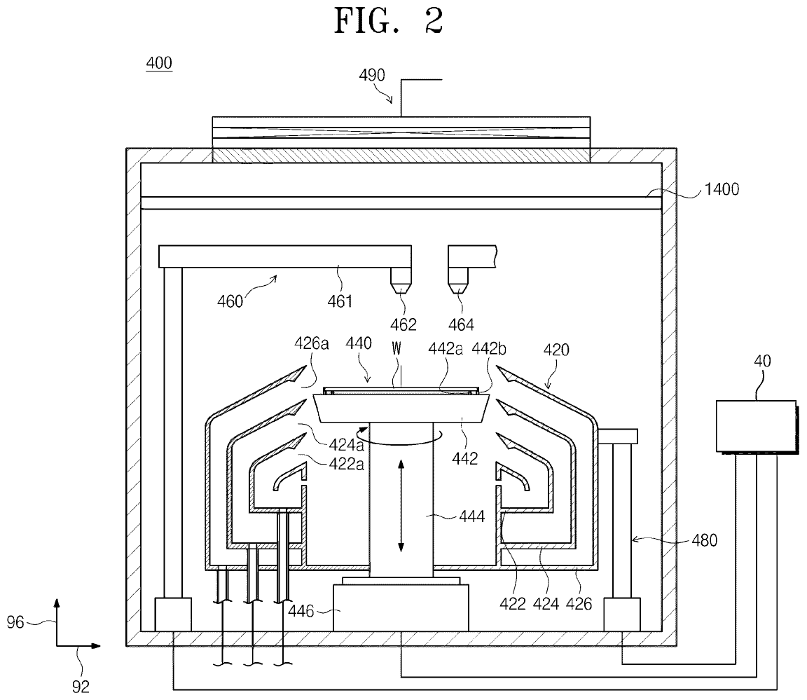

FIG. 2 is a diagram schematically illustrating an exemplary embodiment of the liquid processing chamber 400 of FIG. 1. Referring to FIG. 2, the liquid processing chamber 400 includes a housing 410, a cup 420, a support unit 440, a nozzle unit 460, a lifting unit 480, a fan filter unit 490, an airflow distribution unit 1400, and a controller.

The housing 410 is provided in a generally rectangular parallelepiped shape. The cup 420, the support unit 440, and the liquid supply unit 460 are disposed in the housing 410.

The cup 420 has a process space with an open top, and the substrate W is liquid-treated in the process space. The support unit 440 supports the substrate W in the process space. The liquid supply unit 460 supplies the liquid onto the substrate W supported by the support unit 440. The liquid may be provided in a plurality of types, and may be sequentially supplied onto the substrate W. The lifting unit 480 adjusts a relative height between the cup 420 and the support unit 440.

According to the example, the cup 420 includes a plurality of recovery containers 422, 424, and 426. Each of the recovery containers 422, 424, and 426 has a recovery space of recovering the liquid used for the treatment of the substrate. Each of the recovery containers 422, 424, and 426 is provided in a ring shape surrounding the support unit 440. When the liquid treatment process is in progress, the treatment liquid scattered by the rotation of the substrate W is introduced into the recovery space through inlets 422a, 424a, and 426a of the respective recovery containers 422, 424, and 426. According to the example, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 440 includes a support plate 442 and a driving shaft 444. An upper surface of the support plate 442 may be provided in a generally circular shape, and may have a diameter larger than a diameter of the substrate W. In the center portion of the support plate 442, a support pin 442a is provided to support the rear surface of the substrate W, and the support pin 442a is provided with its upper end protruding from the support plate 442 so that the substrate W is spaced apart from the support plate 442 by a certain distance. A chuck pin 442b is provided to an edge of the support plate 442. The chuck pin 442b is provided to protrude upward from the support plate 442, and supports the lateral portion of the substrate W so that the substrate W is not separated from the support unit 440 when the substrate W is rotated. A drive shaft 444 is driven by a driver 446, is connected to the center of the bottom surface of the substrate W, and rotates the support plate 442 with respect to the central axis thereof.

The nozzle unit 460 includes a first nozzle 462 and a second nozzle 464. The first nozzle 462 supplies a first liquid onto the substrate W. According to the example, when the substrate is processed, the first liquid may require an atmosphere having a lower humidity than a second liquid. Furthermore, the first liquid may be isopropyl alcohol (IPA). The second nozzle 464 supplies the second liquid onto the substrate W. According to the exemplary embodiment, fumes may be further generated in the second liquid compared to the first liquid. The second liquid may be a mixture of Sulfuric Peroxide Mixture (SPM).

The first nozzle 462 and the second nozzle 464 are respectively supported on different arms 461, and the arms 461 may be moved independently. Optionally, the first nozzle 462 and the second nozzle 464 may be mounted on the same arm and moved at the same time.

Optionally, the liquid supply unit may further include one or more nozzles in addition to the first nozzle 462 and the second nozzle 464. Additional nozzles may supply different types of treatment liquids to the substrate. For example, the other type of treatment liquid may be an acid solution or a base solution for removing foreign substances on the substrate. In addition, another type of treatment liquid may be alcohol having surface tension lower than that of water. For example, the alcohol may be isopropyl alcohol.

The lifting unit 480 moves the cup 420 in the up and down direction. By the up and down movement of the cup 420, a relative height between the cup 420 and the substrate W is changed. Accordingly, since the recovery containers 422, 424, and 426 for recovering the treatment liquid are changed according to the type of the liquid supplied to the substrate W, the liquids may be separated and recovered. Unlike the description, the cup 420 may be fixedly installed, and the lifting unit 480 may move the support unit 440 in the vertical direction.

The fan filter unit (FFU) 490 forms descending airflow in an interior space of the housing 410. The fan filter unit 490 includes an airflow supply line 491, a fan 492, and a filter 493. The airflow supply line 491 is connected to the housing 410. The airflow supply line 491 supplies external air to the housing 410. The filter 493 filters contaminants or specific chemical components from air provided from the airflow supply line 491. The fan 492 is installed on the upper surface of the housing 410. The fan 492 is located in a central region on the upper surface of the housing 410. The fan 492 forms descending airflow in the interior space of the housing 410. The fan 492 introduces air from the airflow supply line 491 so that the air flows a down direction.

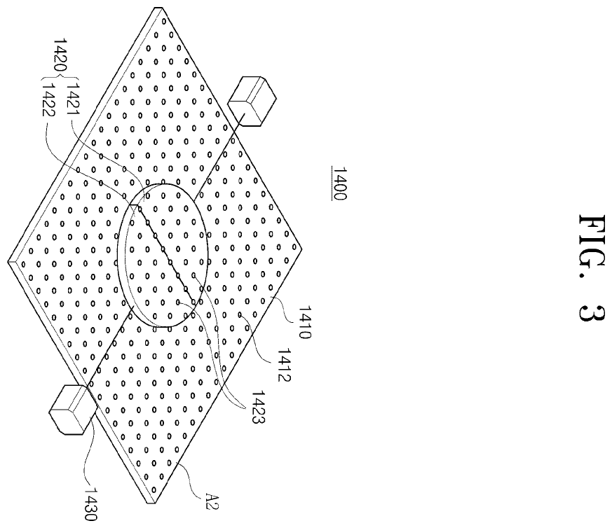

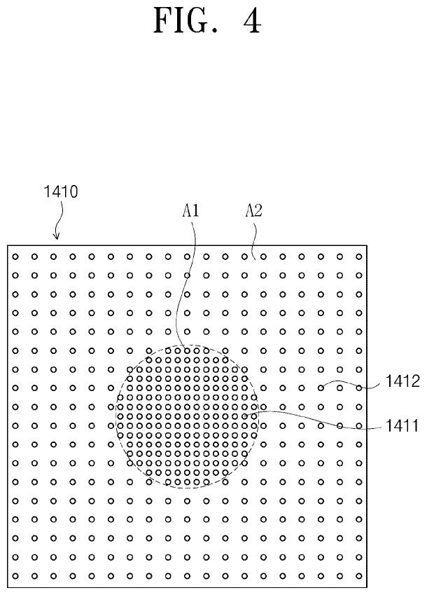

FIG. 3 is a diagram illustrating the airflow distribution unit of FIG. 2, and FIG. 4 is a diagram illustrating a fixing plate of the airflow distribution unit of FIG. 3.

The airflow distribution unit 1400 controls the flow of the descending airflow provided from the fan 492. The airflow distribution unit 1400 is provided below the fan 492. Also, the airflow distribution unit 1400 is disposed above a treatment container 420. The airflow distribution unit 1400 is provided adjacent to the fan 492. The airflow distribution unit 1400 includes a fixing plate 1410, a moving plate 1420, and a driver 1430. The fixing plate 1410 and the moving plate 1420 are provided by being stacked in a vertical direction. According to the example, the moving plate 1420 may be disposed above the fixing plate 1410. The moving plate 1420 is disposed adjacent to the fixing plate 1410. The moving plate may be spaced apart from each other by a small interval to prevent friction between the moving plate 1420 and the fixing plate 1410 when moving relative to the fixing plate.

Referring to FIGS. 3 and 4, the fixing plate 1410 is provided in a rectangular plate shape. The fixing plate 1410 includes a first region A1 and a second region A2. The first region A1 is located in a central region of the fixing plate 1410. When viewed from above, the first region A1 may be provided as an area corresponding to an opening formed by the treatment container 420. The first region A1 may be centered on a central axis of the support unit 440. According to the example, the first region A1 may be provided in a circular shape. A plurality of first holes 1411 are formed in the first region A1. The first hole 1411 is formed to penetrate the upper and lower portions of the first region A1.

The second region A2 is provided to surround the first region A1. A plurality of second holes 1412 are formed in the second region A2. The second hole 1412 is formed to penetrate through upper and lower portions of the fixing plate 1410. The aperture ratio of the first hole 1411 in the first region A1 is provided to be different from the aperture ratio per unit area of the second hole 1412 in the second region A2. According to the present exemplary embodiment, the aperture ratio of the second hole 1412 in the second region A2 is provided to be lower than the aperture ratio per unit area of the first hole 1411 in the first region A1. According to the example, the diameters of the first hole 1411 and the second hole 1412 may be provided to be the same, and a density of the second hole 1412 in the second region A2 may be lower than a density of the first hole 1411. For example, in the first region A1, the first holes 1411 are disposed in a lattice shape, in the second region A2, the second holes 1412 are disposed in a lattice shape, and an interval between the first holes 1411 may be formed to be narrower than an interval between the second holes 1412.

The moving plate 1420 may be provided in the same size as the first region A1. The moving plate 1420 may be moved between a first position B1 and a second position B2. The first position B1 is a position at which the moving plate 1420 is completely deviated from the first region A1 when viewed from above. For example, the second position B1 may overlap the second region A2 when viewed from above. The moving plate 1420 may be provided in a size corresponding to the first region A1. The second position B2 is a position at which the moving plate 1420 completely overlaps the first region A1 when viewed from above.

The moving plate 1420 includes a plurality of third holes 1423 vertically passing through the moving plate 1420. In the moving plate 1420, the aperture ratio per unit area of the third hole 1423 is different from the aperture ratio per unit area of the first hole 1411 in the first region A1. In the moving plate 1420, the aperture ratio per unit area of the third hole 1423 may be equal to the aperture ratio per unit area of the second hole 1412 in the second region A2. The third hole 1423 may be provided with the same diameter as the first hole 1411 and the second hole 1412. The third hole 1423 may be arranged in a lattice shape in the moving plate 1420. Also, when the moving plate 1420 is at the second position B2, the third hole 1423 formed in the moving plate 1420 and the second hole 1412 formed in the second region A2 in the region where the moving plate 1420 and the second region A2 overlap each other when viewed from above are provided in the same pattern and size. When the moving plate 1420 is at the second position A2, all the third holes 1423 formed in the moving plate 1420 completely overlap some of the first holes 1411 formed in the first region A1 when viewed above. However, another portion of the first holes 1411 formed in the first region A1 is blocked by the moving plate 1420. Even though the aperture ratios of the moving plate 1420 and the first region A1 are differently provided, the descending airflow passing through the third hole 1423 may pass through the first hole 1411. According to the example, the moving plate 1420 includes a first plate 1421 and a second plate 1422. The first plate 1421 and the second plate 1422 may be moved by a driver to be described later. The first plate 1421 and the second plate 1422 are provided to be movable in a direction away from or close to each other. The first plate 1421 and the second plate 1422 are provided to be movable between the first position B1 and the second position B2. According to the example, the first plate 1421 and the second plate 1422 are distant from each other at the first position B1. At the second position B2, the first plate 1421 and the second plate 1422 are in contact with each other.

The driver 1430 moves the moving plate 1420 on the fixing plate 1410. According to the example, the driver 1430 moves the first plate 1421 and the second plate 1422. Also, According to the example, a motor may be used as the driver 1430. Optionally, a cylinder may be used as the driver 1430.

The airflow distribution unit 1400 distributes the descending airflow in a mode selected from among a first mode M1 and a second mode M2. The flow of the descending airflow is provided differently in the first mode M1 and the second mode M2.

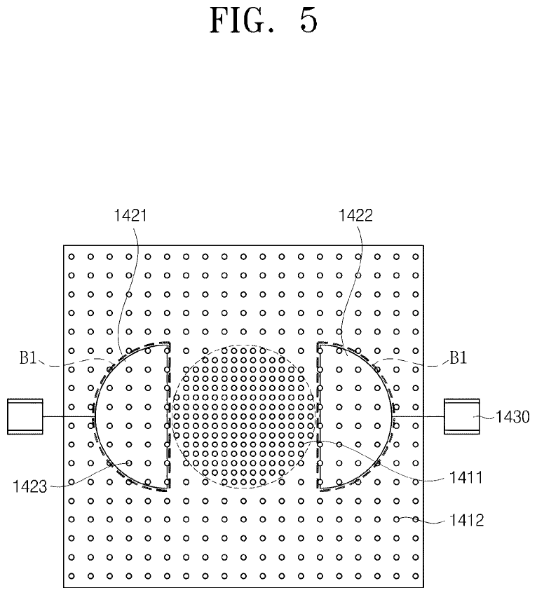

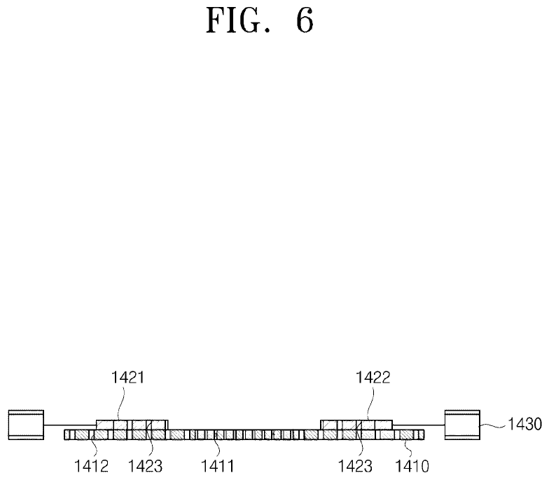

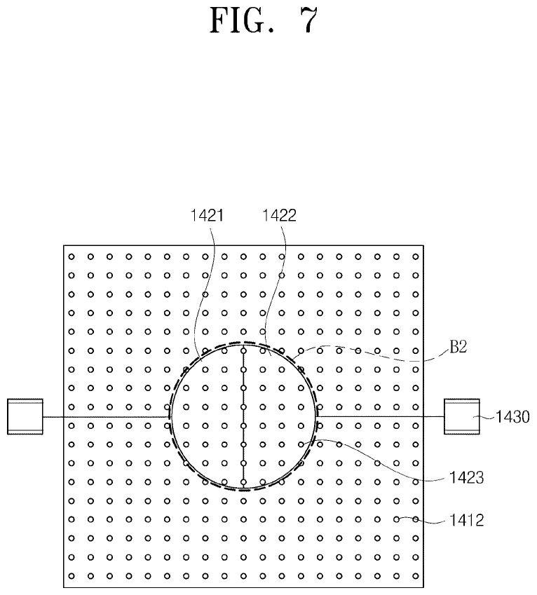

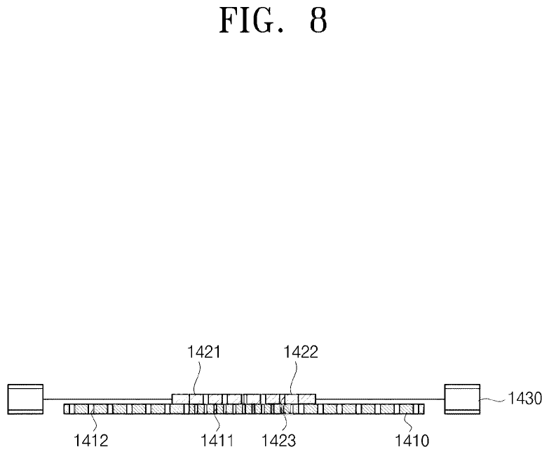

FIGS. 5 and 6 are a diagram and a cross-sectional view of the airflow distribution unit in the first mode when viewed from above, and FIGS. 7 and 8 are a diagram and a cross-sectional view of the airflow distribution unit in the second mode when viewed from above. Dotted lines shown in FIGS. 5 to 8 are for indicating the first position B1 or the second position B2.

The first mode M1 is a mode for providing the descending airflow more uniformly in the interior space than in the second mode M2. The second mode M2 is a mode for allowing the descending airflow to be concentrated in the process space, compared to the first mode M1.

Referring to FIGS. 5 and 6, in the first mode M1, the driver 1430 moves the first plate 1421 and the second plate 1422 in a direction away from each other. The first plate 1421 and the second plate 1422 are located at the first position B1. Accordingly, all the first holes 1411 in the first region A1 are opened. Also, since all the second holes 1412 overlap the third hole 1423 in the region of the second region A2 overlapping the moving plate 1420, all the second holes 1412 formed in the second region A2 are opened. The descending airflow passes through the first hole 1411 of the first region A1. Furthermore, the descending airflow passes through the second hole 1412 of the second region A2 and the third hole 1423 of the moving plate 1420. Since the second hole 1412 and the third hole 1423 are provided to coincide with each other at the first position B1 as described above, the descending airflow passing through the second hole 1412 may directly pass through the third hole 1423. In the first mode M1, the descending airflow directly passes through the first region A1. Since the aperture ratio of the first region A1 is provided to be greater than the aperture ratios of the second region A2 and the moving plate 1420, more descending airflow may flow. For example, since the first region A1 has a size corresponding to that of the opening of the treatment container 420, and is provided at a position corresponding to that of the treatment container 420, the descending airflow may be concentrated in the treatment container 420.

Referring to FIGS. 7 and 8, in the second mode M2, the moving plate 1420 is located at the second position B2. In the second mode M2, the first plate 1421 and the second plate 1422 are in contact with each other. Accordingly, all the second holes 1412 formed in the second region A2 are opened, but only some of the first holes 1411 formed in the first region are opened. The descending airflow formed from the fan 492 passes through the second hole 1412 and the third hole 1423. The descending airflow passing through the third hole 1423 passes through the first hole 1411. Since the third hole 1423 and the first hole 1411 are formed by overlapping each other, the descending airflow passing through the third hole 1423 may pass through the first hole 1411. Since the second region A2 in which the second hole 1412 is formed and the moving plate 1420 in which the third hole 1423 is formed have the same aperture ratio, the descending airflow is constantly distributed to the interior space. While the descending airflow is constantly distributed, the atmosphere of the interior space may be constantly maintained.

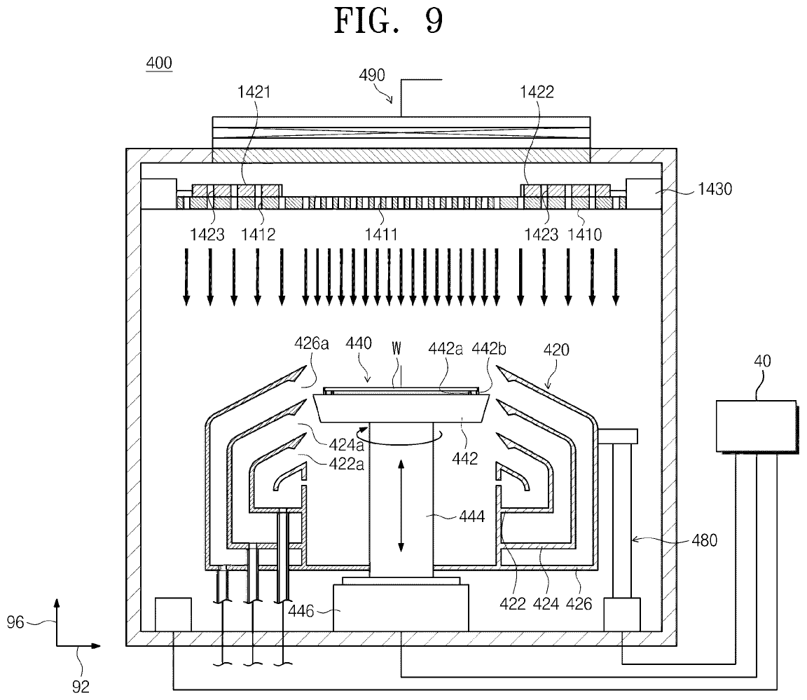

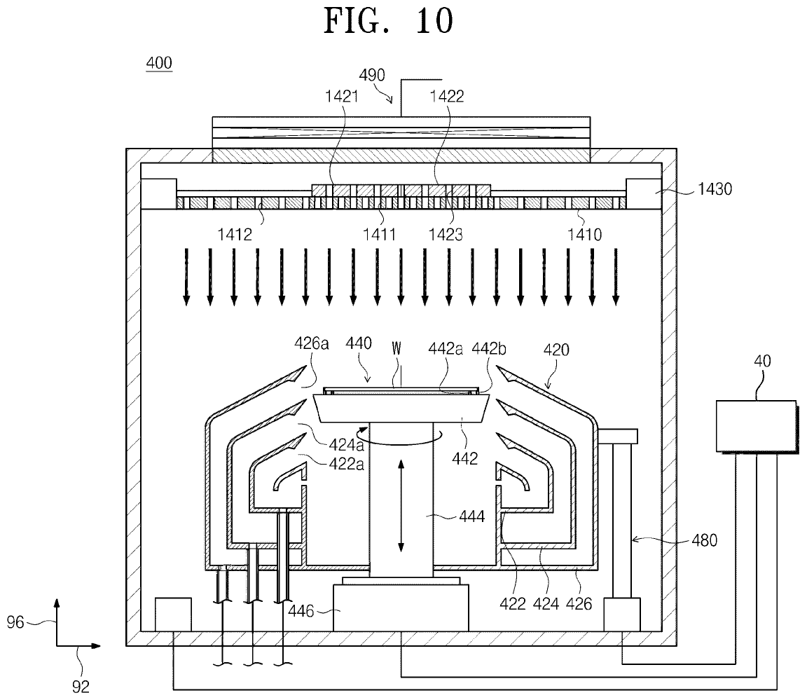

Next, a method of processing a substrate by using the substrate processing apparatus according to an exemplary embodiment of the present invention will be described. FIGS. 9 and 10 are diagrams illustrating a flow of airflow in a liquid processing chamber according to an exemplary embodiment of the present invention in a first process operation and a second process operation. The airflow distributed by the airflow distribution unit 1400 is shown by a plurality of arrows.

The substrate processing method according to the exemplary embodiment of the present invention includes a first process operation S10 and a second process operation S20. The first process operation S10 and the second process operation S20 may be a process of supplying the first liquid and the second liquid to the substrate W at different time points. According to the exemplary embodiment, the first liquid and the second liquid are sequentially supplied to the substrate W. The first liquid and the second liquid may be supplied continuously, and another liquid may be supplied between the supply of the first liquid and the supply of the second liquid.

Referring to FIG. 9, in the first process operation S10, the substrate W is treated by supplying the first liquid to the substrate W positioned in the process space in a state in which descending airflow is provided to the interior space and the process space. In the first process operation S10, the substrate is treated by supplying the first liquid to the substrate positioned in the process space in a state in which descending airflow is provided to the interior space and the process space. In this case, in the first process operation S10, the airflow distribution unit 1400 operates in the first mode M1. In the first process operation S10, descending airflow flows more uniformly to the interior space and the process space than in the second process operation S20. The first liquid may be chemical. For example, the first liquid may be a mixed liquid containing sulfuric acid and hydrogen peroxide mixture (SPM).

Referring to FIG. 10, in the second process operation S20, the substrate W is treated by supplying a second liquid to the substrate W in a state in which descending airflow is provided to the interior space and the process space. In the second process operation S20, the substrate is treated by supplying the second liquid to the substrate in a state in which descending airflow is provided to the interior space and the process space. In this case, in the second process operation S20, the airflow distribution unit 1400 operates in the second mode M2. In the second process operation S20, the descending airflow more intensively flows to the process space than in the first process operation S10. The second liquid may be an organic solvent. For example, the organic solvent may be isopropyl alcohol (IPA). When the substrate W is treated with an organic solvent, an atmosphere of lower humidity may be required than when the substrate is treated with SPM. The airflow distribution unit 1400 is operated in the first mode M1 to uniformly distribute the descending airflow to the interior space, thereby maintaining the interior space in a low-humidity atmosphere. SPM generates more fumes than organic solvents. Fumes are easily scattered to the outside of the treatment container. In the second mode M2, the descending airflow is concentrated in the process space to prevent fumes generated in the process space from being scattered outside the treatment container through the upper portion of the process space.

In the above-described example, it has been described as an example that the moving plate 1420 is divided into two plates 1421 and 1422. However, the present invention is not limited thereto, and the moving plate 1420 may be provided as a single plate or divided into three or more plates.

Furthermore, in the above-described example, the present invention has been described based on the case where the moving plate 1420 is provided on the fixing plate 1410 as an example. However, the present invention is not limited thereto, and the moving plate 1420 may also be provided under the fixing plate 1410. Accordingly, a support member (not shown) for supporting the moving plate 1420 may be provided.

Also, in the above-described example, the present invention has been described based on the case where the first solution is isopropyl alcohol and the second solution is SPM. However, the types of the first solution and the second solution are not limited thereto.

In addition, in the above-described example, the present invention has been described based on the case where the second solution is supplied after the first solution as an example. However, the present invention is not limited thereto, and only the first solution or the second solution may be supplied.

In addition, in the above-described example, the present invention has been described based on the case where the moving plate overlaps the second region A2 of the fixing plate 1410 at the second position B2. However, the present invention is not limited thereto, and the moving plate 1420 may be moved to a region that does not overlap with the fixing plate 1410 at the second position B2.

In addition, in the above-described example, the present invention has been described based on the process of providing the cleaning liquid as a treatment liquid and cleaning the substrate W using the cleaning liquid has been described as an example. However, the present exemplary embodiment is not limited to a cleaning process, but may be applied to various substrate treatment processes using a liquid, such as an etching process, an ashing process, and a development process.

The foregoing detailed description illustrates the present invention. In addition, the above description shows and describes the exemplary embodiments of the present invention, and the present invention may be used in various other combinations, modifications, and environments. That is, changes or modifications are possible within the scope of the concept of the invention disclosed herein, the scope equivalent to the written disclosure, and/or within the scope of skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. In addition, the appended claims should be construed to include other exemplary embodiments as well.

1. An apparatus of treating a substrate, the apparatus comprising:
a housing having an upper wall and providing an interior space;
a treatment container provided in the interior space and providing a process space with an open top;
a support unit for supporting a substrate within the process space;
a liquid supply unit for supplying a treatment liquid on the substrate supported by the support unit;
an exhaust unit for exhausting the process space;
a fan for supplying descending airflow into the interior space; and
an airflow distribution unit that is disposed under the fan and above the treatment container and distributes the descending airflow to the interior space,
wherein the airflow distribution unit is provided to distribute the descending airflow in a mode selected from a first mode and a second mode, and
in the first mode and the second mode, a flow of the descending airflow is provided differently from each other.

2. The apparatus of claim 1, wherein the airflow distribution unit includes:
a fixing plate;
a moving plate stacked on the fixing plate; and
a driver for driving the moving plate, and
the fixing plate has:
a first region where a plurality of first holes penetrating in a vertical direction is formed; and
a second region surrounding the first region and having a plurality of second holes penetrating in the vertical direction,
the moving plate includes a plurality of third holes penetrating in the vertical direction,
the moving plate is provided to be movable between a first position and a second position, and
when viewed from above, the first position is a position where the moving plate overlaps the first region, and the second position is a position where the moving plate is deviated from the first region.

3. The apparatus of claim 2, wherein an aperture ratio per unit area of the first hole in the first region is different from an aperture ratio per unit area of the second hole in the second region.

4. The apparatus of claim 2, wherein an aperture ratio per unit area of the first hole in the first region is greater than an aperture ratio per unit area of the second hole in the second region.

5. The apparatus of claim 3, wherein the first hole, the second hole, and the third hole have the same diameter.

6. The apparatus of claim 2, wherein the moving plate includes a first plate and a second plate,
the first plate and the second plate are provided to be movable in directions facing each other or in directions opposite to each other, and
the driver is provided to move the first plate and the second plate between the first position and the second position.

7. The apparatus of claim 1, wherein the first mode allows a flow of the descending airflow to be concentrated in the process space compared to the second mode.

8. The apparatus of claim 7, wherein the second mode more uniformly provides the flow of the airflow in the interior space than the first mode.

9. The apparatus of claim 2, wherein in the first mode, when viewed from above, the moving plate is located in the second region and the third hole overlaps the second hole.

10. The apparatus of claim 9, wherein in the second mode, the moving plate is located in the first region when viewed from above, and
the third hole overlaps the first hole.

11. The apparatus of claim 4, wherein the driver moves the moving plate to the first position when the treatment liquid is a first liquid, and moves the moving plate to the second position when the treatment liquid is a second liquid.

12. The apparatus of claim 11, wherein when the substrate is treated with the first liquid, fumes are generated more than the second liquid, and
when the substrate is treated with the second liquid, low humidity is required compared to the first liquid.

13. The apparatus of claim 2, wherein the first region has a circular shape, and
when viewed from above, the first region has a size corresponding to an opening of the treatment container through which the descending airflow flows into the process space.

14-18. (canceled)

19. The apparatus of claim 18, wherein when the treatment liquid is a first liquid, the airflow distribution unit operates in the first mode,
in the first mode, the moving plate is located in the second region, the second hole and the third hole overlap, and
when the treatment liquid is a second liquid, the airflow distribution unit operates in the second mode, and
in the second mode, the moving plate is located in the first region, and the first hole and the third hole overlap.

20. The apparatus of claim 19, wherein the first liquid is a treatment liquid that generates more fumes during the substrate treatment than the second liquid, and
the second liquid is a treatment liquid required to have a lower humidity in the process space when treating the substrate than the first liquid.
